(19) United States
(12) Patent Application Publication
(10) Pub. No.: US 2024/0309238 A1
(43) Pub. Date: Sep. 19, 2024

(54) HARDMASK COMPOSITION, HARDMASK LAYER AND METHOD OF FORMING PATTERNS

(71) Applicant: Samsung SDI Co., Ltd., Yongin-si (KR)

(72) Inventor: Yunju Chae, Suwon-si (KR)

(21) Appl. No.: 18/419,879

(22) Filed: Jan. 23, 2024

(30) Foreign Application Priority Data
Mar. 8, 2023 (KR) 10-2023-0030775

(51) Int. Cl. C09D 165/00; C08G 61/02; C08G 61/12; G03F 7/11; H01L 21/027; H01L 21/308; H01L 21/311; H01L 21/3213

(52) U.S. Cl. CPC C09D 165/00; C08G 61/02; C08G 61/124; G03F 7/11; H01L 21/0271; H01L 21/3081; H01L 21/31144; H01L 21/32139; C08G 2261/124; C08G 2261/1422; C08G 2261/18; C08G 2261/228; C08G 2261/314; C08G 2261/3241

(57) ABSTRACT

A hardmask composition, a hardmask layer including a cured product of the hardmask composition, and a method of forming patterns using the hardmask layer including a cured product of the hardmask composition, the hardmask composition includes a polymer including a structural unit represented by Chemical Formula 1; and a solvent:

* [symbol] A-B [symbol] * [Chemical Formula 1]

### CROSS-REFERENCE TO RELATED APPLICATION

This application claims priority to and the benefit of Korean Patent Application No. 10-2023-0030775 filed in the Korean Intellectual Property Office on Mar. 8, 2023, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may use effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

Nowadays, according to small-sizing the pattern to be formed, it may be difficult to provide a fine pattern having an excellent profile by only using some lithographic techniques. Accordingly, an auxiliary layer, called a hardmask layer, may be formed between the material layer and the photoresist layer to provide a fine pattern.

### SUMMARY

The embodiments may be realized by providing a hardmask composition including a polymer including a structural unit represented by Chemical Formula 1; and a solvent:

* [symbol] A-B [symbol] * [Chemical Formula 1]
wherein, in Chemical Formula 1, A is a divalent organic group containing a substituted or unsubstituted C6 to C30 aromatic hydrocarbon ring or a substituted or unsubstituted C3 to C30 heteroaromatic ring, B is a group represented by Chemical Formula 2, and * is a linking point:

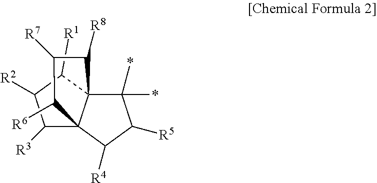

wherein, in Chemical Formula 2, R¹ to R⁸ are each independently a hydrogen atom, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C3 to C30 heteroaromatic group, two adjacent ones of R¹ to R⁸ are separate or are linked to form a ring, provided that two adjacent ones of R¹ to R³ are linked to form at least one ring and two adjacent ones of R⁶ to R⁸ are linked to form at least one ring, and * is a linking point.

A may be a substituted or unsubstituted divalent organic group of a moiety of Group 1 or a moiety of Group 2,

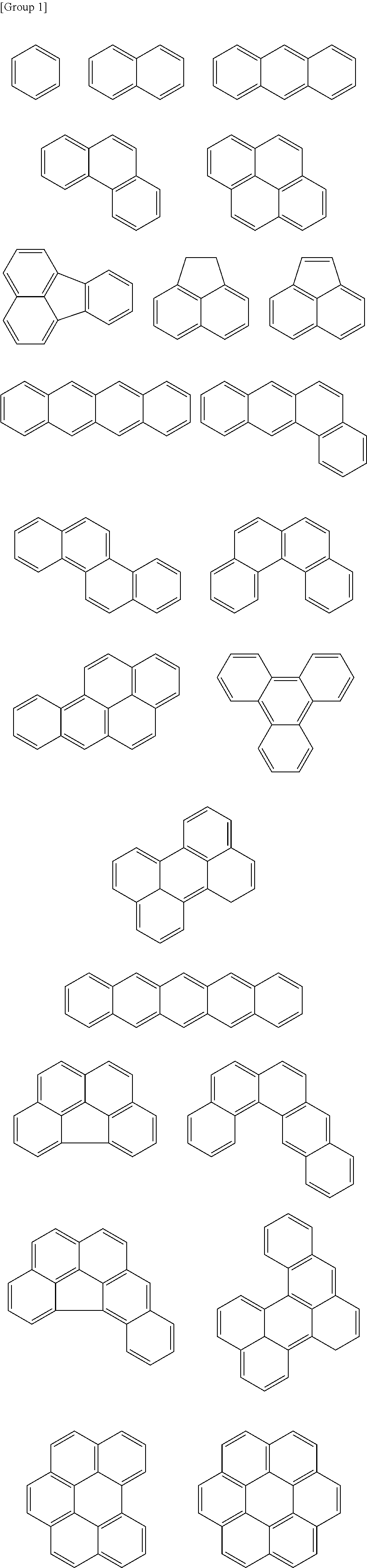

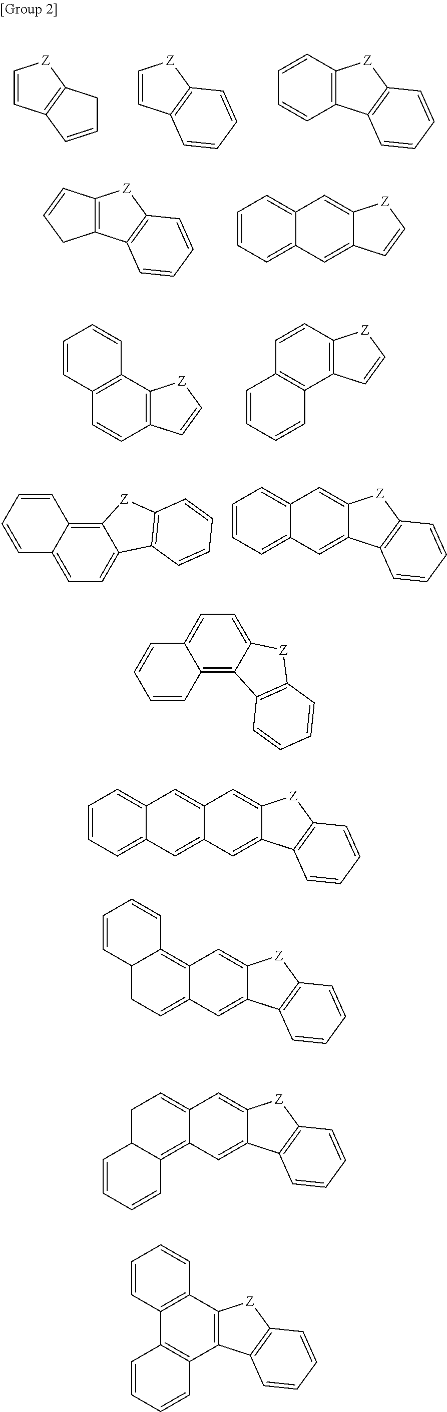

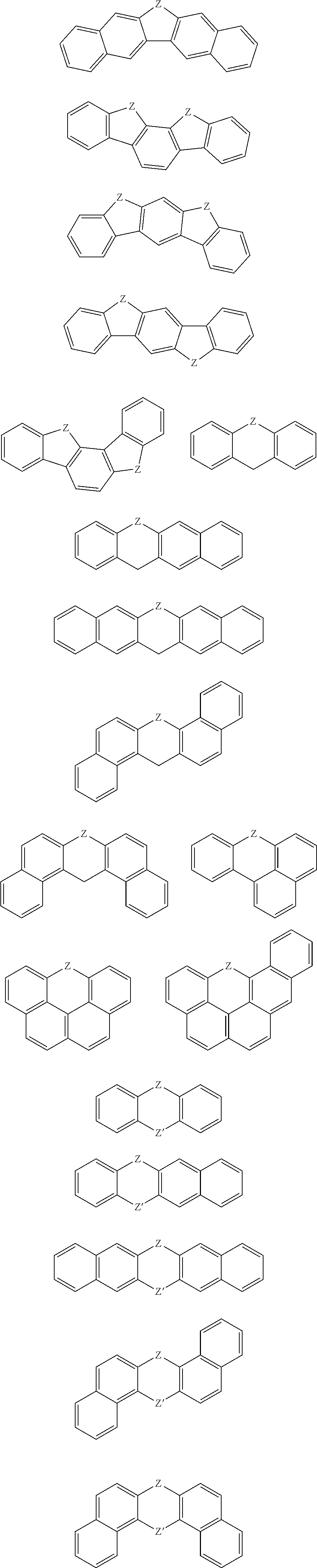

in Group 2, Z and Z′ may each independently be N, O, S, or P.
A may be a substituted or unsubstituted divalent organic group of a moiety of Group 1-1 or a moeity of Group 2-1.

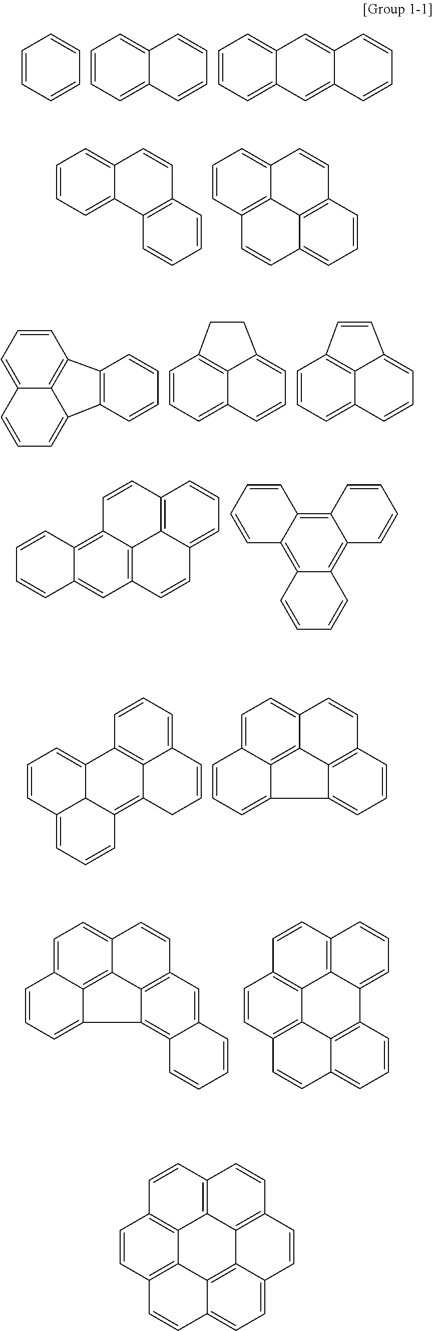

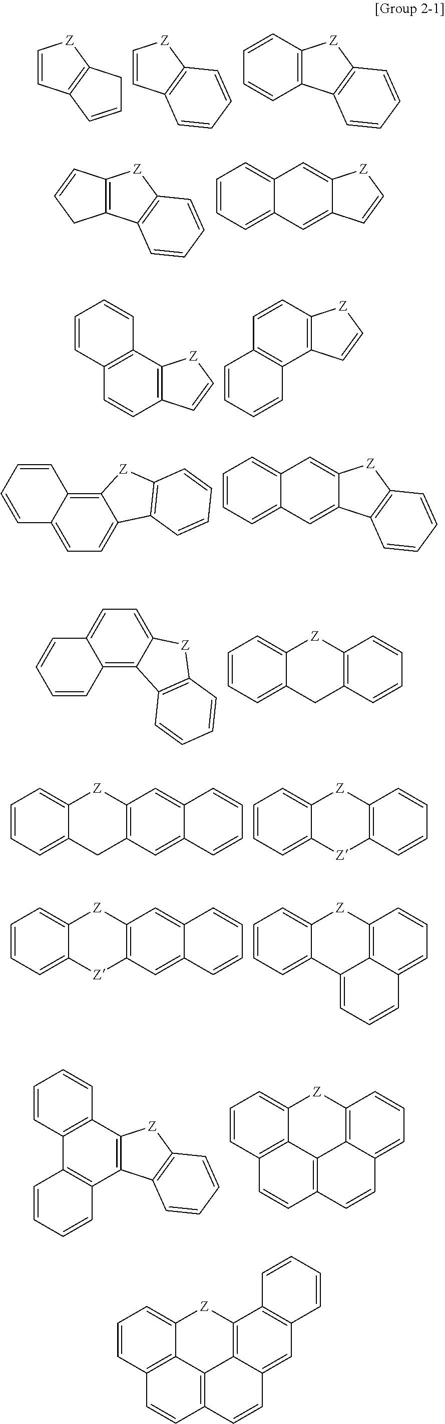

in Group 2-1, Z and Z′ may each independently be N, O, S, or P.
R⁴ and R⁵ of Chemical Formula 2 may be linked to form one ring.

The ring formed by linking two adjacent ones of R¹ to R⁸ may be a substituted or unsubstituted C6 to C20 aromatic hydrocarbon ring, a substituted or unsubstituted C3 to C20 heteroaromatic ring, or a combination thereof.

The ring formed by linking two adjacent ones of R¹ to R⁸ may be a substituted or unsubstituted ring of a moiety of Group 3:

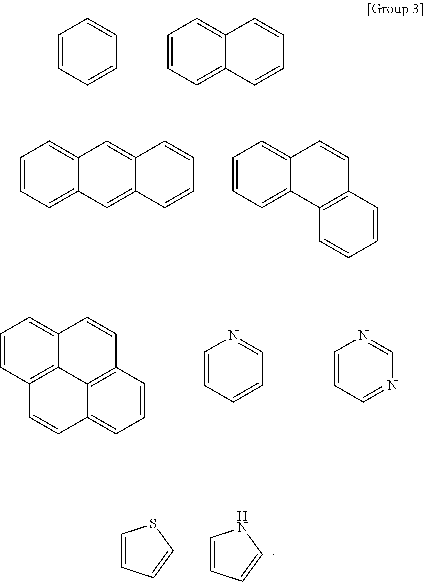

Chemical Formula 2 may be represented by Chemical Formula 2-1:

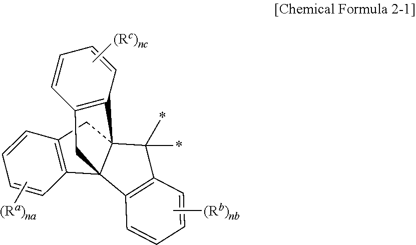

in Chemical Formula 2-1, R^{a} to R^{c} may each independently be deuterium, a hydroxy group, a halogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C1 to C20 heteroalkyl group, or a combination thereof, na to nc may each independently be an integer of 0 to 4, and * is a linking point.

Chemical Formula 1 may be represented by one of Chemical Formula 1-1 to Chemical Formula 1-3:

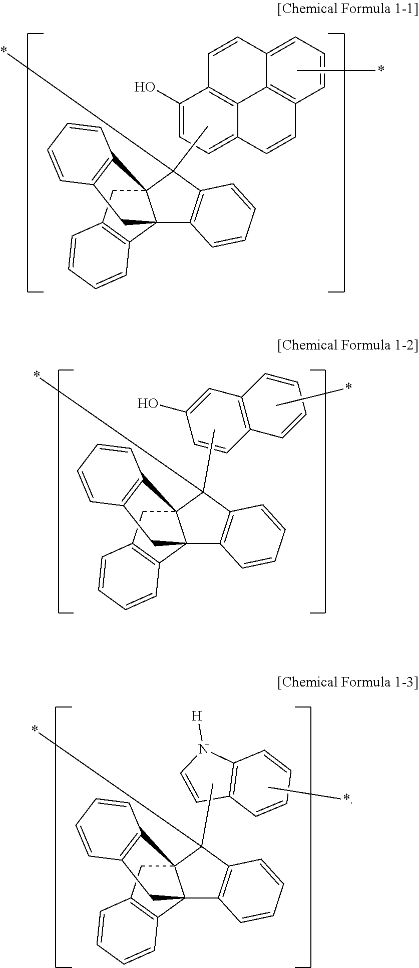

The polymer may have a weight average molecular weight of about 1,000 g/mol to about 200,000 g/mol.

The polymer may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer comprising a cured product of the hardmask composition according to an embodiment.

The embodiments may be realized by providing a method of forming patterns, the method including providing a material layer on a substrate; applying the hardmask composition according to an embodiment on the material layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

Forming the hardmask layer may include heat-treating at about 100° C. to about 1,000° C.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (−H) may include deuterium substitution (−D) or tritium substitution (−T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring. For example, the substituted C6 to C30 aryl group may be fused with another adjacent substituted C6 to C30 aryl group to form a substituted or unsubstituted fluorene ring.

As used herein, when a definition is not otherwise provided, “aromatic hydrocarbon ring” means a group having one or more hydrocarbon aromatic moieties, and includes a form in which hydrocarbon aromatic moieties are linked by a single bond, a non-aromatic fused ring form in which hydrocarbon aromatic moieties are fused directly or indirectly, or a combination thereof as well as non-condensed aromatic hydrocarbon rings, condensed aromatic hydrocarbon rings.

More specifically, the substituted or unsubstituted aromatic hydrocarbon ring is a substituted or unsubstituted phenyl group (phenylene group), a substituted or unsubstituted naphthyl group (naphthylene group), a substituted or unsubstituted anthracenyl group (anthracenylene group), a substituted or unsubstituted phenanthryl group (phenanthrylene group), a substituted or unsubstituted naphthacenyl group (naphthacenylene group), a substituted or unsubstituted pyrenyl group (pyrenylene group), a substituted or unsubstituted biphenyl group (biphenylene group), a substituted or unsubstituted terphenyl group (terphenylene group), a substituted or unsubstituted quaterphenyl group (quaterphenylene group), a substituted or unsubstituted chrysenyl group (chrysenylene group), a substituted or unsubstituted triphenylenyl group (triphenylenylene group), a substituted or unsubstituted perylenyl group (perylenylene group), a substituted or unsubstituted indenyl group (indenylene group), a combination thereof, or a combined fused ring of the foregoing groups, but is not limited thereto.

As used herein, when a definition is not otherwise provided, “hetero” refers to one including at least one heteroatom selected from N, O, S, Se, and P.

As used herein, when a definition is not otherwise provided, “hetero aromatic ring” refers to one including at least one heteroatom selected from N, O, S, Se, and P within the aromatic ring.

As used herein, when a definition is not otherwise provided, “heteroalkyl group” refers to a group including a hetero element selected from N, O, S, P and Si instead of one or more carbon atoms forming an alkyl group.

As used herein, the polymer may include both an oligomer and a polymer.

Unless otherwise specified in the present specification, the “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

A hardmask composition according to some embodiments may include, e.g., a polymer including a structural unit represented by Chemical Formula 1, and a solvent.

* [symbol] A-B [symbol] * [Chemical Formula 1]

In Chemical Formula 1, A may be or may include, e.g., a divalent organic group containing a substituted or unsubstituted C6 to C30 aromatic hydrocarbon ring, or a substituted or unsubstituted C3 to C30 heteroaromatic ring. B may be or may include, e.g., a group represented by Chemical Formula 2. * is a linking point:

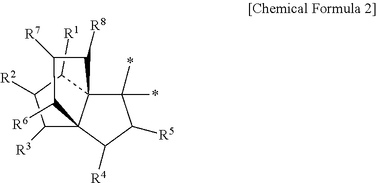

In Chemical Formula 2, R¹ to R⁸ may each independently be or include, e.g., a hydrogen atom, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C3 to C30 hetero aromatic hydrocarbon group. In an implementation, two adjacent ones of R¹ to R⁸ may be separate or may be linked to form a ring.

In an implementation, two adjacent ones of R¹ to R³ may be linked form at least one ring.

In an implementation, two adjacent ones of R⁶ to R⁸ may be linked to form at least one ring.
* is a linking point.

In an implementation, the polymer included in the hardmask composition according to some embodiments may include an aromatic hydrocarbon ring or a heteroaromatic ring and at the same time may include a quaternary carbon, so that the carbon content in the polymer may increase and a hardmask layer formed from a hardmask composition containing the polymer may have high etch resistance.

In an implementation, as the polymer may contain a hydrocarbon that forms a three-dimensional structure with three pentagonal rings sharing one side, as shown in Chemical Formula 2, and shrinkage during curing of the hardmask composition including it may be minimized, voids or defects in the hardmask layer formed from this may be minimized, planarization characteristics of the layer may be improved, and etch resistance and heat resistance of the hardmask layer may be further improved.

In an implementation, A may be a substituted or unsubstituted divalent organic group of a moiety of Group 1 or a moiety of Group 2. For example, any of the moieties of Group 1 and Group 2 may be unsubstituted, as illustrated, or may be substituted as described above.

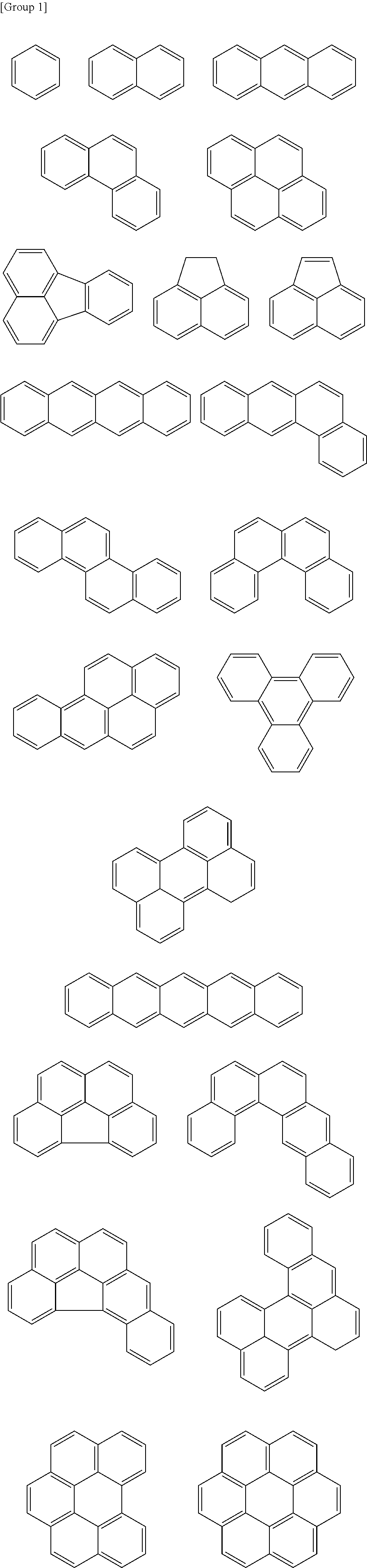

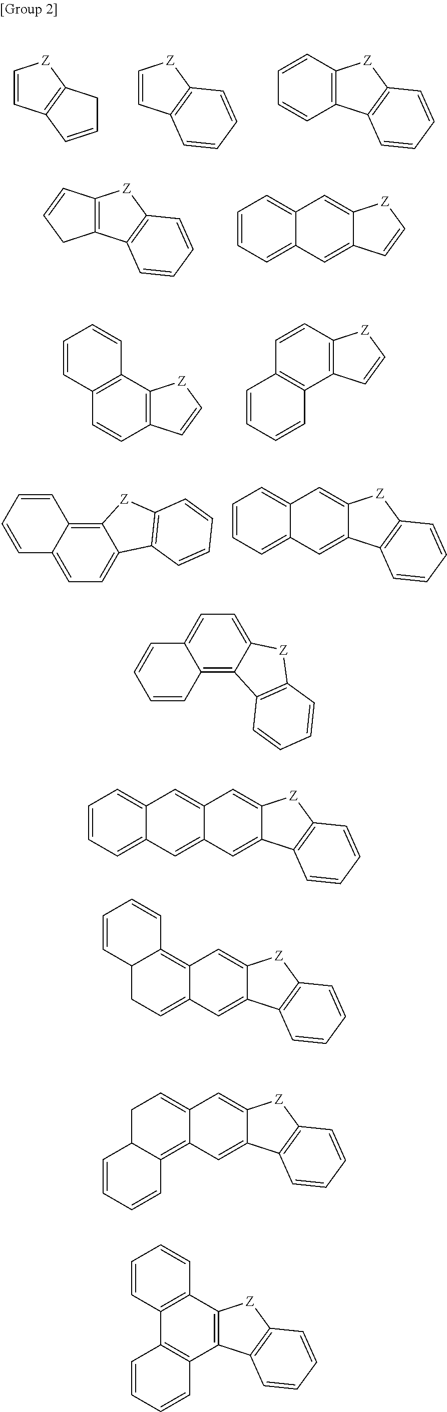

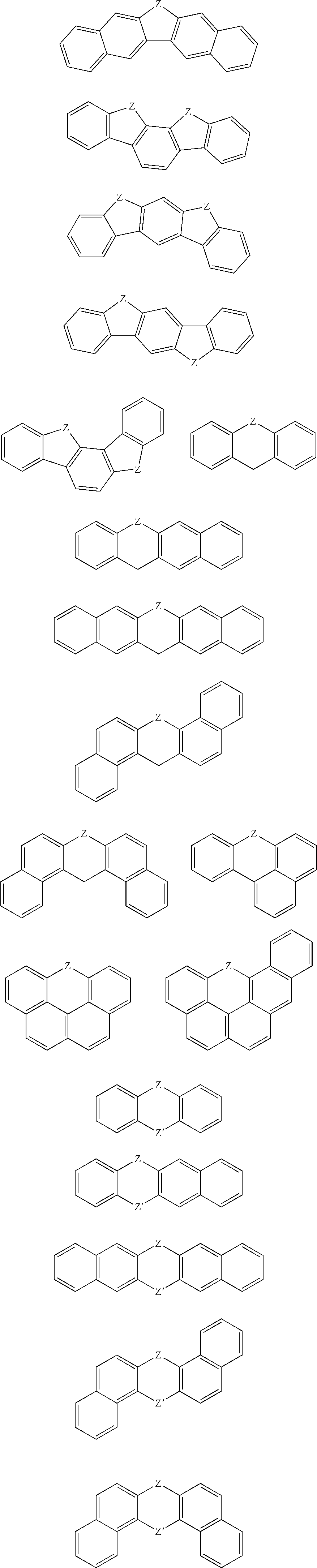

In Group 2, Z and Z′ may each independently be, e.g., N, O, S, or P.

In an implementation, A may be, e.g., a substituted or unsubstituted divalent organic group of a moiety of Group 1-1 or a moiety of Group 2-1.

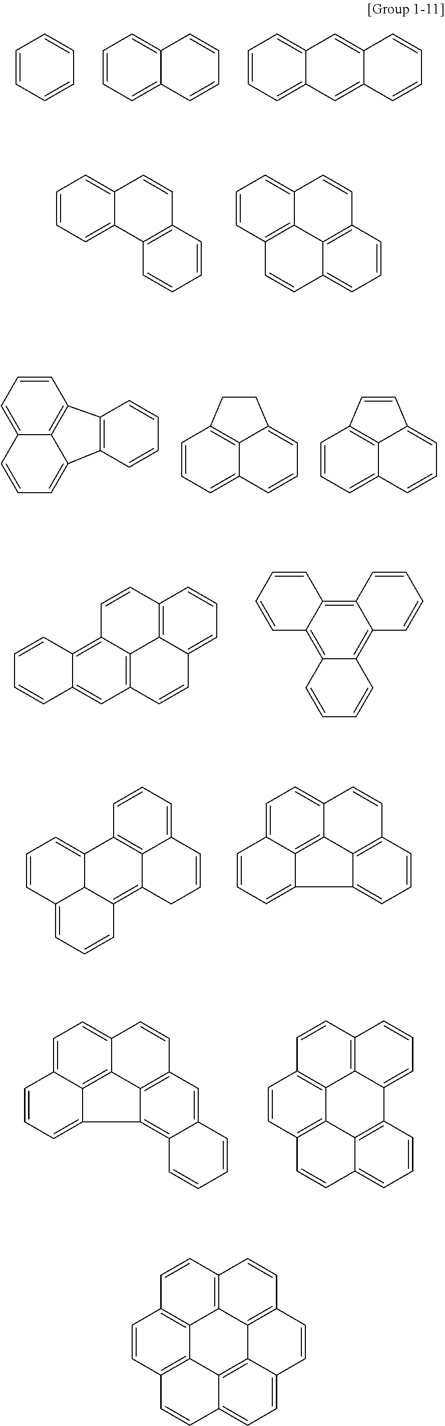

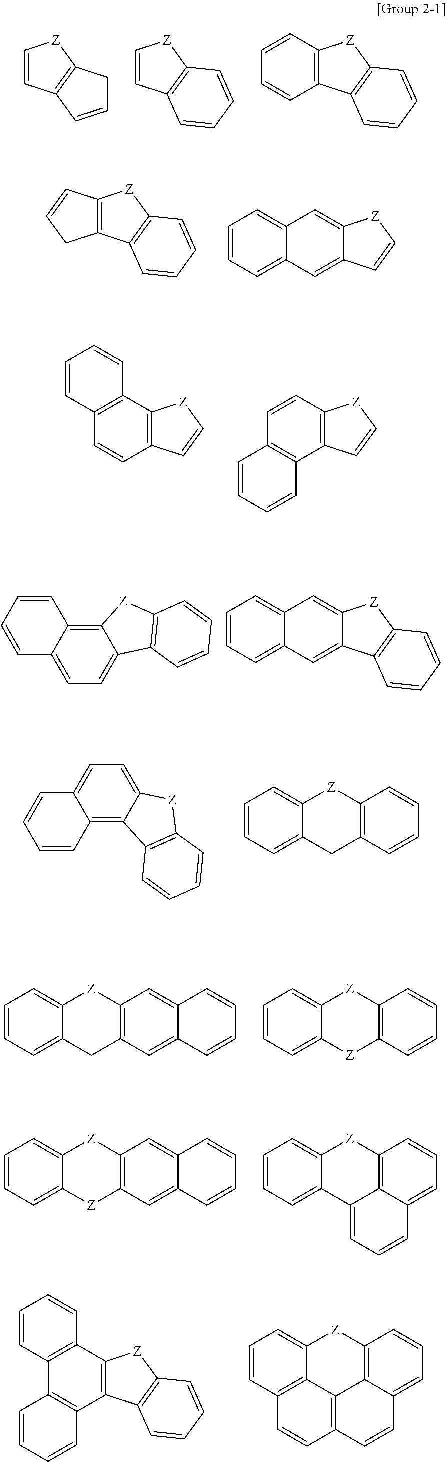

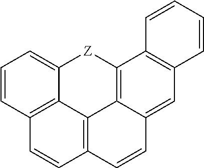

In Group 2-1, Z and Z′ may each independently be, e.g., N, O, S, or P.

In an implementation, A may be, e.g., a substituted or unsubstituted naphthalene group, a substituted or unsubstituted pyrene group, or a substituted or unsubstituted indole group.

In an implementation, R⁴ and R⁵ of Chemical Formula 2 may be linked to form one ring. A volume of the hydrocarbon ring represented by Chemical Formula 2 may be adjusted depending on whether the rings of R⁴ and R⁵ are formed. In an implementation, R⁴ and R⁵ of Chemical Formula 2 may be linked to form additional rings, and the volume of the hydrocarbon ring represented by Chemical Formula 2 further increases, which may have an effect of making the polymer more soluble in the solvent.

The ring formed by linking two adjacent R¹ to R⁸ may be a substituted or unsubstituted C6 to C20 aromatic hydrocarbon ring, a substituted or unsubstituted C3 to C20 heteroaromatic ring, or a combination thereof.

In an implementation, in Chemical Formula 2, R¹ and R² may be linked to form one ring and R⁶ and R⁷ may be linked to form one ring; R² and R³ may be linked to form one ring and R⁶ and R⁷ may be linked to form one ring; R¹ and R² may be linked to form one ring and R⁷ and R⁸ may be linked to form one ring; or R² and R³ may be linked to form one ring and R⁷ and R⁸ may be linked to form one ring.

In an implementation, R¹ and R², and R² and R³ may be linked to form one ring, and at the same time, R⁶ and R⁷, or R⁷ and R⁸ may be linked to form one ring. In an implementation, R¹ and R², and R² and R³ may be linked to form one ring, and the two rings formed by R¹ to R³ may or may not share one side.

In an implementation, the ring formed by linking two adjacent ones of R¹ to R⁸ may be a substituted or unsubstituted ring of a moiety of Group 3.

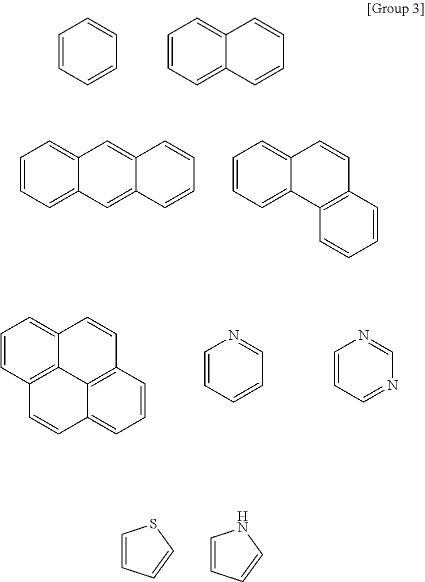

In an implementation, Chemical Formula 2 may be represented by Chemical Formula 2-1.

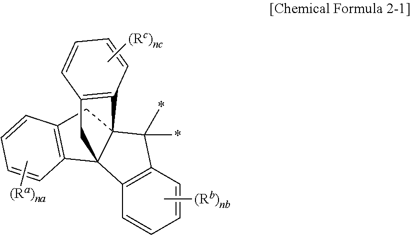

In Chemical Formula 2-1, R^{a} to R^{c} may each independently be, e.g., deuterium, a hydroxy group, a halogen atom, a substituted or unsubstituted C1 to C20 alkyl group, a C2 to C20 alkenyl group, a substituted or unsubstituted C2 to C20 alkynyl group, a substituted or unsubstituted C3 to C20 cycloalkyl group, a substituted or unsubstituted C1 to C20 heteroalkyl group, or a combination thereof. na to nc may each independently be, e.g., an integer of 0 to 4. * is a linking point.

In an implementation, Chemical Formula 1 may be represented by, e.g., one of Chemical Formula 1-1 to Chemical Formula 1-3.

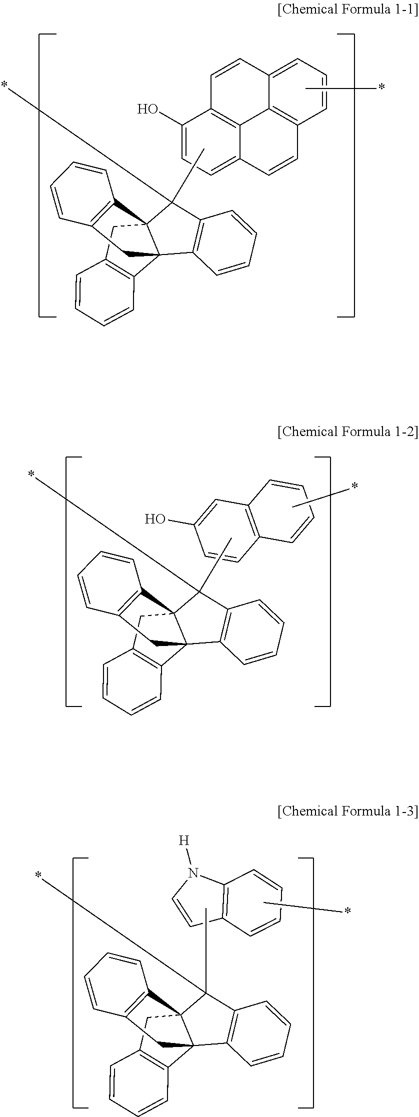

The polymer may have a weight average molecular weight of about 1,000 g/mol to about 200,000 g/mol. In an implementation, the polymer may have a weight average molecular weight of, e.g., about 1,000 g/mol to about 150,000 g/mol, about 1,000 g/mol to about 100,000 g/mol, about 1,000 g/mol to about 10,000 g/mol, or about 1,200 g/mol to about 5,000 g/mol. By having a weight average molecular weight within the above ranges, the carbon content and solubility in the solvent of the hardmask composition including the above polymer can be adjusted and optimized.

The polymer may be included in an amount of, e.g., about 0.1 wt % to about 30 wt %, based on a total weight of the hardmask composition. In an implementation, the polymer may be included in an amount of, e.g., about 0.2 wt % to about 30 wt/o, about 0.5 wt % to about 30 wt %, about 1 wt % to about 30 wt %, about 1 wt % to about 25 wt %, or about 1 wt % to about 20 wt %. By including the polymer within the above ranges, a thickness, a surface roughness, and a planarization degree of the hardmask may be easily adjusted.

The hardmask composition according to some embodiments may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. The solvent may be a suitable solvent that has sufficient solubility or dispersibility for the polymer.

In an implementation, the hardmask composition may further include an additive, e.g., a surfactant, a crosslinking agent, a thermal acid generator, or a plasticizer.

The surfactant may include, e.g., a fluoroalkyl compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

In an implementation, a hardmask layer including a cured product of the aforementioned hardmask composition may be provided.

Hereinafter, a method of forming patterns using the aforementioned hardmask composition is described.

A method of forming patterns according to some embodiments includes providing a material layer on a substrate, applying a hardmask composition including the aforementioned polymer and solvent on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer. The substrate may be, e.g., silicon wafer, a glass substrate, or a polymer substrate.

The material layer may be a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process and a second heat-treating process.

In an implementation, the heat-treating of the hardmask composition may include, e.g., one heat-treating process performed at about 100° C. to about 1000° C. for about 10 seconds to about 1 hour. In an implementation, the heat-treating may be performed under an atmosphere of air, nitrogen, or an atmosphere having oxygen concentration of about 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 100° C. to about 400° C. for about 10 seconds to about 1 hour, about 100° C. to about 1,000° C., about 300° C. to about 1,000° C., about 500° C. to about 1,000° C., or about 500° C. to about 800° C. for about 10 seconds to about 1 hour. In an implementation, the first and second heat-treating may be performed under an atmosphere of air, nitrogen, or an oxygen concentration of about 1 wt % or less.

By performing at least one of the steps of heat-treating the hardmask composition at a high temperature, e.g., of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include at a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may be formed of a material, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Examples 1 to 3: Synthesis of Polymers

### Synthesis Example 1

1-hydroxypyrene (43.5 g, 0.2 mol), triptindan-9-one (61.68 g, 0.2 mol), p-toluenesulfonic (p-TSA) acid (1.3 g, 6 mmol), and 78.2 g of propylene glycol monomethyl ether acetate (PGMEA) were put in a flask and then, stirred at 100° C. for 2 to 15 hours to perform a polymerization reaction. The reaction was completed when a sample taken from the polymerization reactant at every one hour had a weight average molecular weight of 2,000 to 3,500 g/mol. After the polymerization reaction was completed, the reactant was slowly cooled to ambient temperature and added to 40 g of distilled water and 400 g of methanol and then, vigorously stirred to form precipitates. The precipitates were dissolved in 80 g of PGMEA and then, vigorously stirred by using 320 g of methanol and 320 g of water to form precipitates. The obtained precipitates were dissolved in 80 g of PGMEA. This purification process of twice forming the precipitates was performed three times in total. After the purification, the obtained polymer was dissolved in 80 g of PGMEA, and the methanol and the distilled water remaining in the solution were removed under a reduced pressure to obtain a polymer including a structural unit represented by Chemical Formula 1-1. (Mw: 2,300 g/mol)

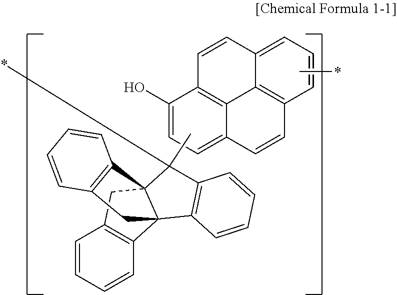

### Synthesis Example 2

A polymer including a structural unit represented by Chemical Formula 1-2 was obtained in the same manner as in Example 1 except that 2-hydroxynaphthalene was used instead of the 1-hydroxypyrene. (Mw: 2,100 g/mol)

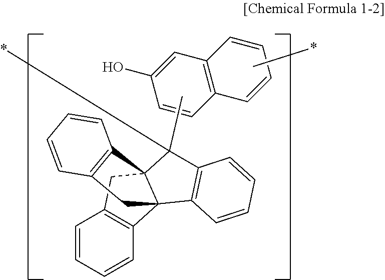

### Synthesis Example 3

A polymer including a structural unit represented by Chemical Formula 1-3 was obtained in the same manner as in Example 1 except that 1-indole was used instead of the 1-hydroxypyrene. (Mw: 2,000 g/mol)

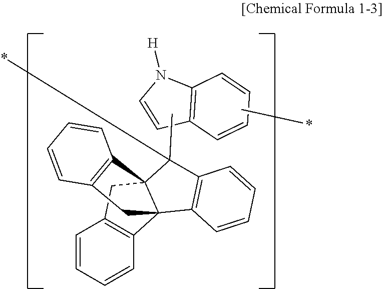

### Comparative Synthesis Example 1

2-phenyl-1H-indole (19.3 g, 0.1 mol), 9-fluorenone (18 g, 0.1 mol), p-TSA (9.5 g, 0.05 mol), and dioxane were stirred at 100° C. for 2 to 15 hours to perform a polymerization reaction. The reaction was completed when a sample taken from the polymerization reactant at every 1 hour had a weight average molecular weight of 2,000 to 3,500 g/mol. After the reaction was completed, 100 g of hexane was added thereto to extract 1,4-dioxane, methanol was added thereto to form precipitates, and the precipitates were filtered and treated with methanol to remove monomers therein to obtain a polymer represented by Chemical Formula P. (Mw: 2,500 g/mol).

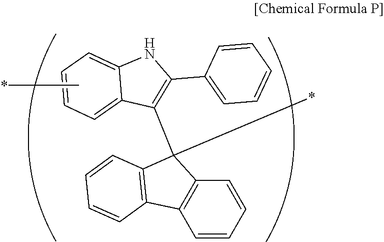

### Comparative Synthesis Example 2

350.41 g (1 mol) of 9.9-bis(4-hydroxyphenyl)fluorene, 3.08 g (0.02 mol) of diethylsulfate, and 350 g of propylene glycol monomethyl ether were put in a 3 L four-necked flask equipped with a mechanical agitator and a cooling tube, and 350 g of propylene glycol monomethyl ether was added thereto and then, stirred, while maintaining a temperature at 115° C., to completely dissolve them. After 10 minutes, 166.22 g (1 mol) of 1,4-bismethoxy methylbenzene was added dropwise thereto and then, reacted at the same temperature for 15 hours. In order to terminate the reaction, 2.98 g of triethanol amine as a neutralizer was added thereto. After the reaction was complete, a mixture of water/methanol was used to remove acid, and subsequently, methanol was used to remove a low molecular weight material containing an oligomer and a monomer to obtain a polymer including a structural unit represented by Chemical Formula Q. (Mw: 8,800 g/mol, polydispersity: 1.9)

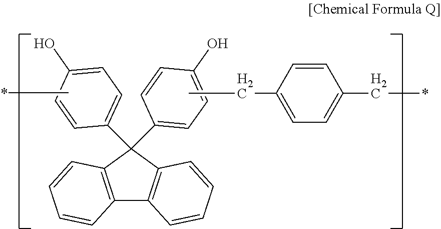

### Examples and Comparative Examples: Preparation of Hardmask Compositions

### Example 1

A hardmask composition was prepared by using 3 g of the polymer according to Synthesis Example 1 in 10 g of PGMEA and filtering the solution with a 0.1 μm TEFLON (tetrafluoroethylene) filter.

### Example 2

A hardmask composition was prepared in the same manner as in Example 1 except that the polymer of Synthesis Example 2 was used instead of the polymer of Synthesis Example 1.

### Example 3

A hardmask composition was prepared in the same manner as in Example 1 except that the polymer of Synthesis Example 3 was used instead of the polymer of Synthesis Example 1.

### Comparative Example 1

A hardmask composition was prepared in the same manner as in Example 1 except that the polymer of Comparative Synthesis Example 1 was used instead of the polymer of Synthesis Example 1.

### Comparative Example 2

A hardmask composition was prepared in the same manner as in Example 1 except that the polymer of Comparative Synthesis Example 2 was used instead of the polymer of Synthesis Example 1.

### Evaluation 1: Heat Resistance Evaluation

10.0 wt % of each of the hardmask compositions according to Examples 1 to 3 and Comparative Examples 1 and 2 was spin-coated on a silicon wafer. The formed film was baked on a hot plate at 240° C. for 1 minute and then, measured with respect to a thickness and baked at 400° C. for 2 minutes and then, remeasured with respect to a thickness. The thicknesses of the film at two temperatures were used to calculate a reduction rate according to Calculation Equation 1 and thereby, digitize relative heat resistance of a hardmask layer. The results are shown in Table 1.

(Thin film thickness after baking at 240° C.−Thin film thickness after baking at 400° C.)/Thin film thickness after baking at 240° C. [Calculation Equation 1]

TABLE 1

| | Thin film thickness reduction rate (%) |
|---|---|
| Example 1 | 17 |
| Example 2 | 13 |
| Example 3 | 15 |
| Comparative Example 1 | 29 |
| Comparative Example 2 | 24 |

Referring to Table 1, hardmasks formed of the hardmask compositions of Examples 1 to 3 exhibited a lower thin film thickness decrease rate than hardmasks formed of the hardmask compositions of Comparative Examples 1 and 2 under the conditions, and the hardmasks formed of hardmask compositions of Examples 1 to 3 exhibited excellent heat resistance, compared with the hardmasks formed of the hardmask compositions of Comparative Examples 1 and 2.

### Evaluation 2: Etch Resistance Evaluation

Each of the hardmask compositions of Examples 1 to 3 and Comparative Examples 1 and 2 was spin-on coated on a silicon wafer and heat-treated at 400° C. for 120 seconds to form a hardmask film and then, measured with respect to a thickness by using a film thickness meter of ST5000 made by K-MAC Co., Ltd. Subsequently, the thin film was dry-etched by using N₂/O₂ mixed gas (50 mT/300 W/10O₂/50 N₂) and CFₓ gas (100 mT/600 W/42 CF₄/600 Ar/15 O₂) respectively for 60 seconds and 120 seconds and then, remeasured with respect to a thickness. Two thicknesses of the thin film before and after the dry etching and etching time were used to calculate a bulk etch rate (BER) according to Calculation Equation 2, and the results are shown in Table 2.

Etch rate (Å/sec)=(initial thin film thickness−thin film thickness after etching)/etching time (sec) [Calculation Equation 2]

TABLE 2

Bulk etch rate (Å/s)

| | N₂/O₂ etch | CFx etch |
|---|---|---|
| Example 1 | 23.6 | 25.1 |
| Example 2 | 23.5 | 25.3 |
| Example 3 | 23.2 | 25.3 |
| Comparative Example 1 | 28.4 | 30.2 |
| Comparative Example 2 | 25.7 | 28.3 |

Referring to Table 2, the hardmasks of the hardmask compositions according to Examples 1 to 3 exhibited a lower etch rate during the N₂/O₂ mixed gas and CFx gas etching than the hardmasks of the hardmask compositions according to Comparative Examples 1 and 2, and the hardmasks of the hardmask compositions according to according to Examples 1 to 3 exhibited excellent etch resistance, compared with the hardmasks of the hardmask compositions according to Comparative Examples 1 and 2.

By way of summation and review, there is a constant trend in a semiconductor industry to reduce a size of chips. To respond to this, the line width of the resist patterned in lithography technology may have a size of, e.g., several tens of nanometers. Therefore, a height that can withstand the line width of the resist pattern may be limited, and there may be cases where the resists do not have sufficient resistance in the etching step. In order to compensate for this, an auxiliary layer, which is called a hardmask layer, may be used between a material layer to be etched and a photoresist layer. This hardmask layer may serve as an interlayer that transfers a fine pattern of the photoresist through selective etching and thus, the hardmask layer may have etch resistance and crosslinking characteristics to withstand the etching process required for pattern transfer.

Some hardmask layers may be formed in a chemical or physical deposition method and may have low economic efficiency due to a large-scale equipment and a high process cost. Accordingly, a spin-coating technique for forming a hardmask layer has recently been developed. The spin-coating technique may be an easier process to conduct than the other methods, and a hardmask layer formed therefrom may exhibit excellent gap-fill characteristics and planarization characteristics, and the etch resistance required for the hard mask layer tends to decrease somewhat.

Accordingly, a hardmask composition may be applied by the spin-coating technique and may help secure equivalent etch resistance to that of the hardmask layer formed in the chemical or physical deposit method. Accordingly, in order to improve the etch resistance of a hardmask layer, research on maximizing a carbon content of the hardmask composition is being actively made.

Accordingly, the hardmasks formed of the hardmask compositions according to some embodiments exhibited excellent etch resistance and heat resistance.

By including a polymer with an increased carbon content including aromatic hydrocarbon rings, or heteroaromatic rings, not only the etch resistance of the hardmask layer made therefrom may be improved, by introducing a three-dimensional hydrocarbon ring along with quaternary carbon into the polymer, the carbon content in the polymer may be maximized, further improving the etch resistance and heat resistance of the hardmask layer manufactured therefrom, and at the same time, by minimizing shrinkage upon curing of the hardmask composition containing the polymer, voids or defects in the hardmask layer may be minimized, thereby improving the flattening characteristics of the film, and furthermore, the solubility of the polymer in solvents may be further increased due to a side chain group having a three-dimensional structure.

One or more embodiments may provide a hardmask composition that can be effectively applied to a hardmask layer.

The hardmask composition according to some embodiments has a low shrinkage rate when cured, and a hardmask layer formed therefrom may help secure excellent heat resistance and etch resistance.

One or more embodiments may provide a hardmask composition, a hardmask layer including a cured product of the hardmask composition, and a method of forming patterns using the hardmask composition.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent:
* [symbol] A-B [symbol] * [Chemical Formula 1]
wherein, in Chemical Formula 1,
A is a divalent organic group containing a substituted or unsubstituted C6 to C30 aromatic hydrocarbon ring or a substituted or unsubstituted C3 to C30 heteroaromatic ring,
B is a group represented by Chemical Formula 2, and
* is a linking point: 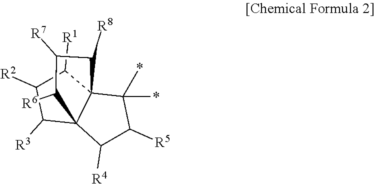
wherein, in Chemical Formula 2,
R¹ to R⁸ are each independently a hydrogen atom, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C3 to C30 heteroaromatic group,
two adjacent ones of R¹ to R⁸ are separate or are linked to form a ring, provided that two adjacent ones of R¹ to R³ are linked to form at least one ring and two adjacent ones of R⁶ to R⁸ are linked to form at least one ring, and
* is a linking point.

2. The hardmask composition of claim 1, wherein:
A is a substituted or unsubstituted divalent organic group of a moiety of Group 1 or a moiety of Group 2, 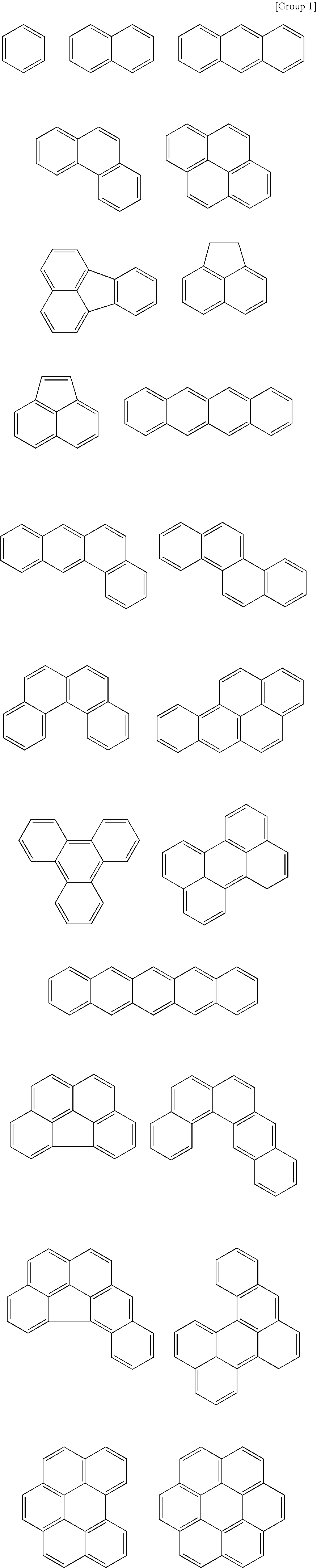 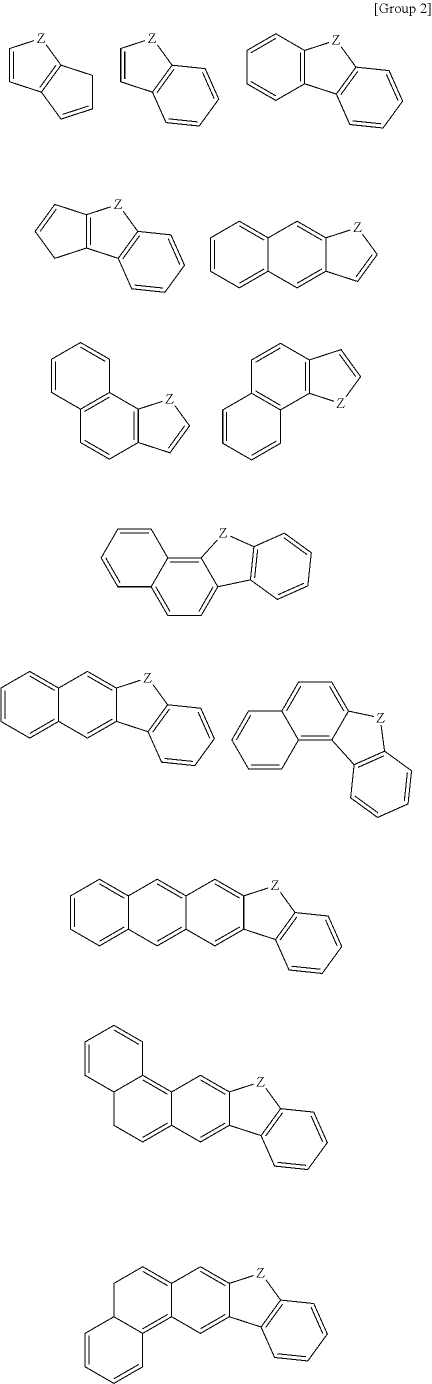 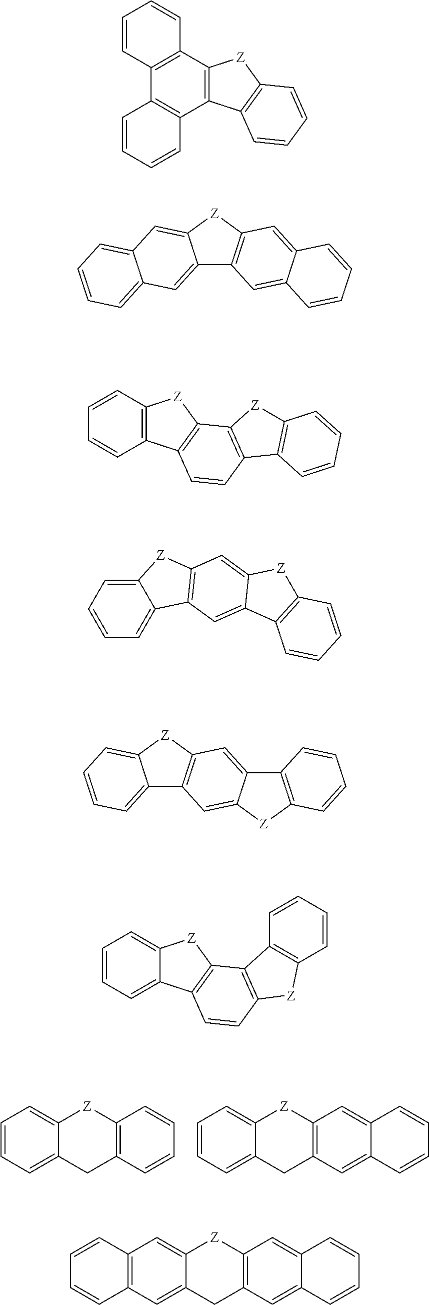 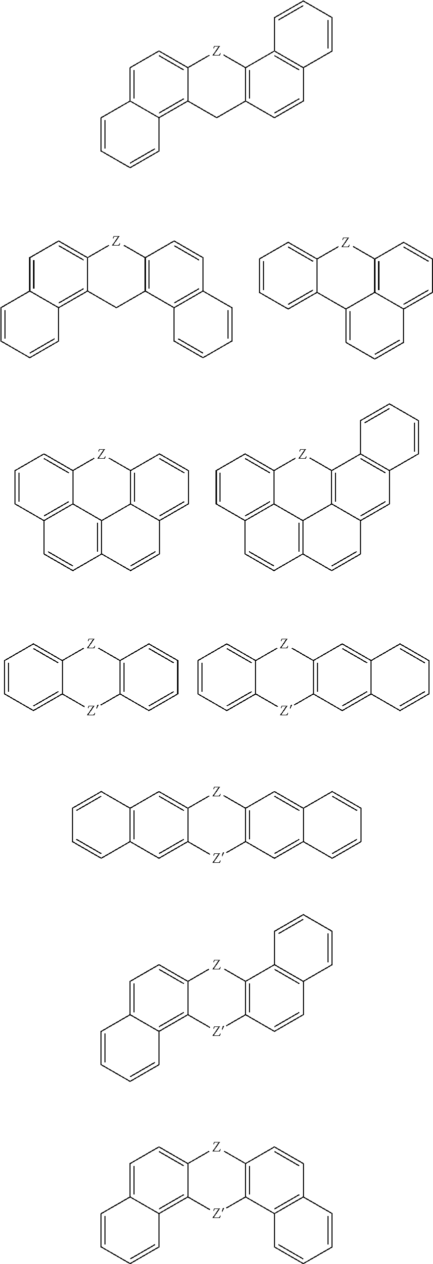
in Group 2, Z and Z′ are each independently N, O, S, or P.

3. The hardmask composition of claim 1, wherein:
A is a substituted or unsubstituted divalent organic group of a moiety of Group 1-1 or a moiety of Group 2-1, 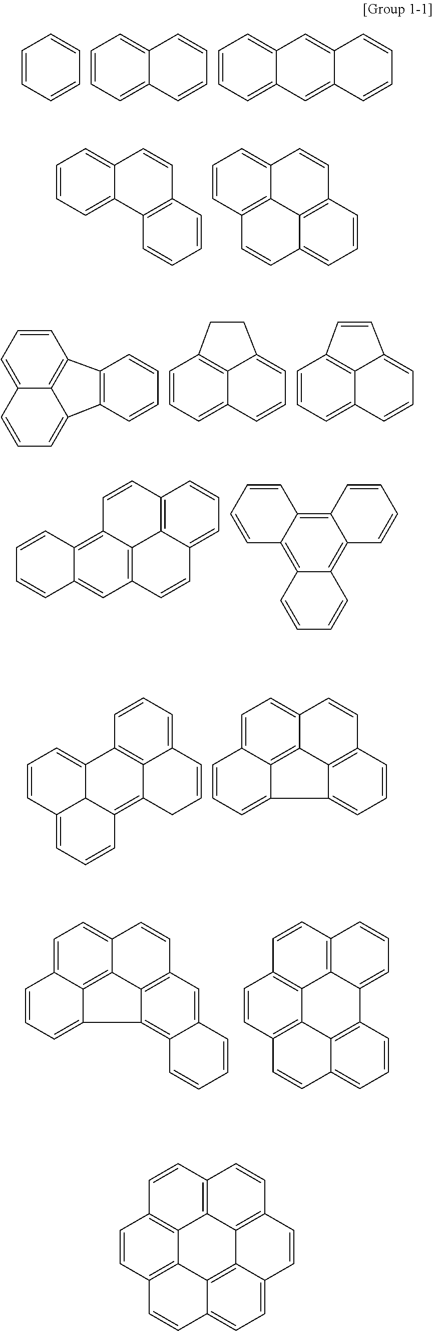 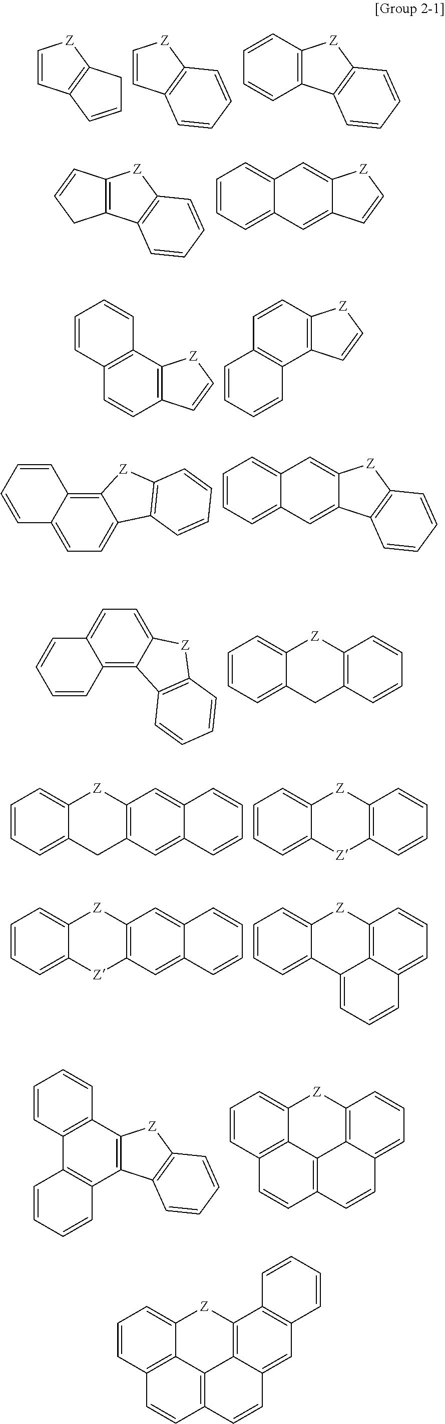
in Group 2-1, Z and Z′ are each independently N, O, S, or P.

4. The hardmask composition of claim 1, wherein R⁴ and R⁵ of Chemical Formula 2 are linked to form one ring.

5. The hardmask composition of claim 1, wherein the ring formed by linking two adjacent ones of R¹ to R⁸ is a substituted or unsubstituted C6 to C20 aromatic hydrocarbon ring, a substituted or unsubstituted C3 to C20 heteroaromatic ring, or a combination thereof.

6. The hardmask composition of claim 1, wherein the ring formed by linking two adjacent ones of R¹ to R⁸ is a substituted or unsubstituted ring of a moiety of Group 3:

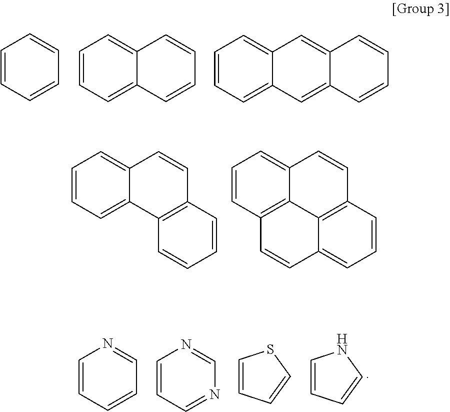

7. The hardmask composition of claim 1, wherein:
Chemical Formula 2 is represented by Chemical Formula 2-1: 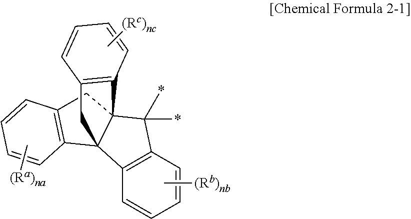
in Chemical Formula 2-1,
R^{a} to R^{c} are each independently deuterium, a hydroxy group, a halogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C1 to C20 heteroalkyl group, or a combination thereof,
na to nc are each independently an integer of 0 to 4, and
* is a linking point.

8. The hardmask composition of claim 1, wherein Chemical Formula 1 is represented by one of Chemical Formula 1-1 to Chemical Formula 1-3:

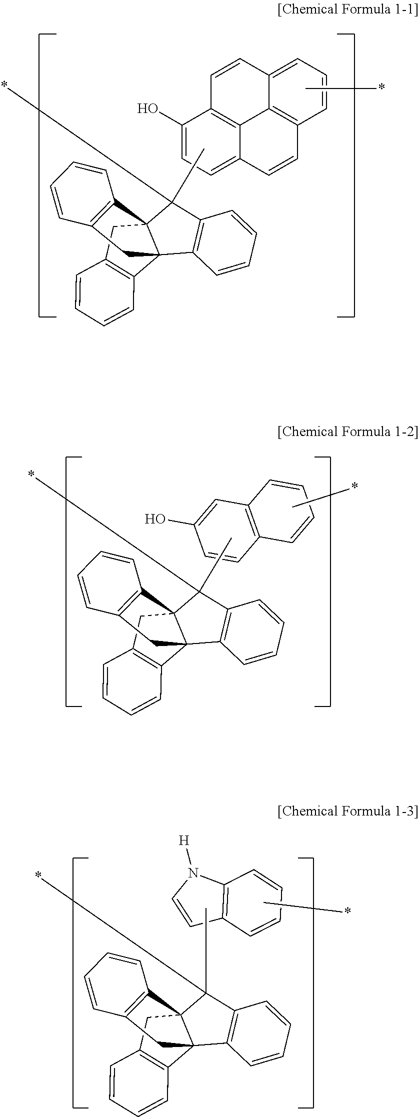

9. The hardmask composition of claim 1, wherein the polymer has a weight average molecular weight of about 1,000 g/mol to about 200,000 g/mol.

10. The hardmask composition of claim 1, wherein the polymer is included in an amount of about 0.1 wt % to about 30 wt %, based on a total weight of the hardmask composition.

11. The hardmask composition of claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

12. A hardmask layer comprising a cured product of the hardmask composition of claim 1.

13. A method of forming patterns, the method comprising:
providing a material layer on a substrate;
applying the hardmask composition of claim 1 on the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

14. The method of claim 13, wherein forming the hardmask layer includes heat-treating at about 100° C. to about 1,000° C.
